(19) United States
(12) Patent Application Publication
(10) Pub. No.: US 2007/0047304 A1
(43) Pub. Date: Mar. 1, 2007

(54) Non-volatile semiconductor memory device and method of manufacturing the same

(75) Inventors: Seong-Soo Lee, Seongnam-si (KR); Young-Wook Park, Suwon-si (KR); Jang-Bin Yim, Yongin-si (KR); Bum-Su Kim, Yongin-si (KR); Du-Hyun Cho, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/508,919

(22) Filed: Aug. 24, 2006

(30) Foreign Application Priority Data
Aug. 31, 2005 (KR) 10-2005-0080734

(51) Int. Cl. G11C 11/34

(52) U.S. Cl. 365/185.05

(57) ABSTRACT

In a non-volatile memory device having a relatively high operation performance and a method of manufacturing the same, a substrate may be prepared to include an active region on which a conductive structure is located and defined by a field region in which an isolation layer is formed. A tunnel oxide layer may be formed on the active region of the substrate. A floating gate pattern may be formed on the tunnel oxide layer, and may include a lower part having a first width that is formed on the tunnel oxide layer and an upper part having a second width that is formed on the lower part, where the second width is substantially smaller than the first width. A dielectric layer pattern may be formed on the floating gate pattern, and a control gate pattern may be formed on the dielectric layer pattern. Accordingly, the non-volatile memory device may have an improved efficiency in programming and erasing data.

### PRIORITY CLAIM

A claim of priority is made to Korean Patent Application No. 2005-80734 filed on Aug. 31, 2005, the contents of which may be herein incorporated by reference in their entirety.

### BACKGROUND

1. Field

Example embodiments relate generally to a non-volatile semiconductor memory device and a method of manufacturing the non-volatile semiconductor memory device. For example, example embodiments relate to a non-volatile semiconductor memory device having an improved coupling ratio and a method of manufacturing the non-volatile semiconductor memory device having an improved coupling ratio.

2. Description of the Related Art

A non-volatile semiconductor memory device is able to maintain data stored therein even when a power supply is cut off. For example, a flash memory device, one type of non-volatile semiconductor memory device, is capable of electrical programming or erasing stored data.

A non-volatile semiconductor memory device may include a floating gate that may store carriers, such as electrons and holes. A tunnel oxide layer may be formed on a substrate, and a floating gate, a dielectric layer and/or a control gate may be sequentially formed on the tunnel oxide layer.

In a flash memory device, data may be electrically stored into the flash memory device and read out from the flash memory device using a Fowler-Nordheim tunneling method or a channel hot electron injection method.

Regarding the Fowler-Nordheim tunneling method, a relatively high voltage may be applied to the control gate to generate a relatively high electric field around the tunnel oxide layer, and electrons in the semiconductor substrate may be injected into the floating gate through the tunnel oxide layer due to the relatively high electric field.

In the channel hot electron injection method, a relatively high voltage may be applied to the control gate and the drain region to generate hot electrons around the drain region and the hot electrons may be injected into the floating gate through the tunnel oxide layer. Accordingly, both the Fowler-Nordheim tunneling method and the channel hot electron injection method may require a relatively high electric field around the tunnel oxide layer. Thus, a relatively high coupling ratio may be required in order to generate the relatively high electric field around the tunnel oxide layer.

The coupling ratio C/R may be represented by the following Equation 1.
C/R=C_{ONO}/(C_{ONO}+C_{TUN}) (1)

Referring to Equation 1, C_{ONO} denotes a capacitance between the control gate and the floating gate and C_{TUN} denotes a capacitance of the tunnel oxide layer interposed between the floating gate and the semiconductor substrate. In order to increase the coupling ratio C/R, an effective surface area of the floating gate which may be overlapped with the control gate may be increased. However, the increased effective surface area of the floating gate may make it more difficult to increase an integration degree of the non-volatile semiconductor memory device because the space between the floating gate and adjacent other floating gate may be narrow.

As a result, a cell disturbance, may cause an overflowing electrical effect on neighboring cells adjacent to an operating cell corresponding to a selected address while storing or erasing data. For example, a cell disturbance may be more frequently generated when a thickness of the floating gate is increased because the opposed side areas of the floating gates may be increased, so that an improvement of the coupling ratio caused by the thickness increase of the floating gate may have a limitation due to the cell disturbance.

### SUMMARY

Example embodiments may provide non-volatile semiconductor memory devices having an improved efficiency in programming and erasing data.

Example embodiments may provide methods of manufacturing the non-volatile semiconductor memory devices having an improved efficiency in programming and erasing data.

The non-volatile semiconductor memory device may include a substrate including an active region on which a conductive structure may be located and defined by a field region composed of an isolation layer; a tunnel oxide layer formed on the active region of the substrate; a floating gate pattern including a lower pattern having a first width that may be formed on the tunnel oxide layer and an upper pattern having a second width that may be formed on the lower pattern, where the second width may be substantially smaller than the first width; a dielectric layer pattern formed on the floating gate pattern; and/or a control gate pattern formed on the dielectric layer pattern.

In an example embodiment, the upper pattern may be located on a central portion of the lower pattern or on an edge portion of the lower pattern.

In an example embodiment, the floating gate pattern may include an “L” shape or an inverted “T” or a “⊥” shape.

In an example embodiment, the floating gate pattern may include a polysilicon film and/or a metal film.

In an example embodiment, the field region may include a recessed portion at a central portion thereof.

According to an example embodiment, there is provided a method of manufacturing a non-volatile semiconductor memory device. An active region may be defined on the substrate by an isolation layer in a field region. A tunnel oxide layer may be formed on the active region of the substrate. A line-shaped preliminary floating gate pattern may be formed on the tunnel oxide layer, and the preliminary floating gate pattern may include a lower pattern having a first width that may be formed on the tunnel oxide layer and an upper pattern having a second width that may be formed on the lower pattern, where the second width may be substantially smaller than the first width. A dielectric layer may be formed on the preliminary floating gate pattern, and a control gate layer may be formed on the dielectric layer. The control gate layer, the dielectric layer and the preliminary floating gate may be sequentially patterned to form a control gate pattern, a dielectric layer pattern and a floating gate pattern, respectively, on the active region of the substrate.

In an example embodiment, the preliminary floating gate pattern may be formed as follows: a line-shaped first preliminary floating gate pattern may be formed on the tunnel oxide layer; a top surface of the first preliminary floating gate pattern may be planarized; and a mask pattern through which the first preliminary floating gate pattern may be partially exposed and formed on the first preliminary floating gate pattern. The first preliminary floating gate pattern may be partially etched to a predetermined or desired depth measured from the substrate using the mask pattern as an etching mask, so that a lower portion of the first preliminary floating gate pattern may have the first width and an upper portion of the first preliminary floating gate pattern may have the second width. An edge portion or a central portion of the first preliminary floating gate pattern may be covered with the mask pattern and a top surface of the isolation layer may be relatively higher than a surface of the substrate in the active region.

In an example embodiment, the first preliminary floating gate pattern may be formed as follows: a conductive layer may be formed on the substrate to a thickness to fill a gap between isolation layers adjacent to each other; and the conductive layer may be planarized until a top surface of the isolation layer may be exposed.

In an example embodiment, an upper portion of the isolation layer may be further removed from the substrate after forming the first preliminary floating gate pattern. In addition, an upper portion of the isolation layer may be further removed from the substrate after forming the preliminary floating gate pattern.

In an example embodiment, the control gate layer may be formed as follows: a polysilicon film may be formed on the dielectric layer to fill a gap between the preliminary floating gate patterns adjacent to each other; and a conductive film including a metal on the polysilicon layer may be formed on the polysilicon film.

According to example embodiments, a line-shaped preliminary floating gate pattern may include a lower pattern having a first width and an upper pattern having a second width smaller than the first width so that a distance between the floating gate patterns adjacent to each other may increase and a cell disturbance between neighboring floating gate patterns may be sufficiently suppressed or reduced.

Further, as the cell disturbance may be suppressed or reduced, a height of the floating gate pattern may be increased, thereby increasing a capacitance (C_{ONO}) between the control gate and the floating gate. Therefore, data may be programmed or erased with relatively high operation efficiency in the memory device.

### BRIEF DESCRIPTION OF THE DRAWINGS

Example embodiments will become more apparent by description thereof with reference to the accompanying drawings, in which:

FIG. 1 is a perspective view illustrating a non-volatile semiconductor memory device in accordance with an example embodiment;

FIGS. 2 to 6 are example perspective views illustrating a method of manufacturing a non-volatile semiconductor memory device in accordance with an example embodiment;

FIGS. 7 to 9 are example perspective views illustrating a method of manufacturing a non-volatile semiconductor memory device in accordance with another example embodiment; and

FIG. 10 is an example perspective view illustrating a non-volatile semiconductor memory device in accordance with another example embodiment.

### DESCRIPTION OF EXAMPLE EMBODIMENTS

Hereinafter, example embodiments will be described in detail with reference to the accompanying drawings. It is understood that characteristics (e.g., thicknesses of layers, regions, etc.) illustrated in the drawings may be not drawn to scale. In the drawings, the sizes and relative sizes of layers and regions may be exaggerated for clarity.

Example embodiments are provided so that this disclosure will be thorough and complete, and will fully convey the scope of example embodiments to those skilled in the art. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there may be no intervening elements or layers present. Like numbers refer to like elements throughout. As used herein, the term “and/or” may include any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that may be schematic illustrations of idealized example embodiments (and intermediate structures) of example embodiments. As such, variations from the shapes of the illustrations as a result, for example, of manufacturing techniques and/or tolerances, may be to be expected. Thus, Example embodiments should not be construed as limited to the particular shapes of regions illustrated herein but may be to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures may be schematic in nature and their shapes may be not intended to illustrate the actual shape of a region of a device and may be not intended to limit the scope of example embodiments.

Unless otherwise defined, all terms (including technical and scientific terms) used herein have the same meaning as commonly understood by one of ordinary skill in the relevant art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

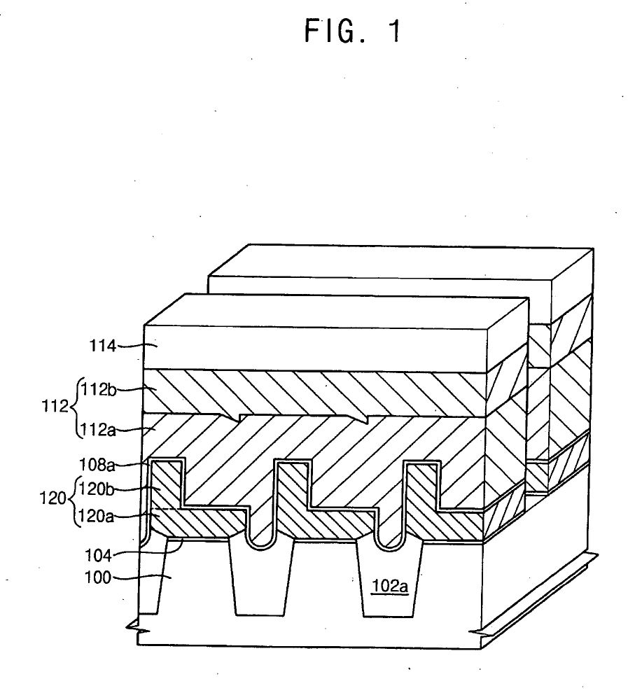

FIG. 1 is a perspective view illustrating a non-volatile semiconductor memory device in accordance with an example embodiment.

Referring to FIG. 1, a non-volatile semiconductor memory device in accordance with an example embodiment may include a substrate 100, a tunnel oxide layer 104, a floating gate pattern 120, a dielectric layer pattern 108a and a control gate pattern 112.

The substrate 100 may include an isolation layer 102a that divides the substrate 100 into a field region and an active region. The isolation layer 102a may extend along the substrate 100. The direction in which the isolation layer 102a is extended may be defined as a first direction.

The isolation layer 102a @may have a recess at an upper central portion thereof. That is, a top surface of the isolation layer 102a may be lower at the central portion than at outer portions that may be closer to the active region of the substrate.

The tunnel oxide layer 104 may be formed in the active region. The tunnel oxide layer 104 may include oxide having relatively good electrical characteristics, so that carriers, such as electrons or holes, may migrate through the tunnel oxide layer 104. For example, the tunnel oxide layer 104 may include silicon oxide that may be formed by a thermal oxidation process.

The floating gate pattern 120 may be located on the isolation layer 102a and the tunnel oxide layer pattern 104. The floating gate pattern 120 may include a lower pattern 120a having a first width that covers the tunnel oxide layer pattern 104 and an upper pattern 120b having a second width and that vertically protrudes from an outer or upper portion of the lower pattern 120a. The second width may be smaller than the first width. Thus, in an example embodiment, the floating gate pattern 120 may have an L shape.

The floating gate pattern 120 may include polysilicon doped with impurities. According to an example embodiment, a bottom of the floating gate pattern 120 makes contact with the tunnel oxide layer 104 and the isolation layer 102a at outer portions of neighboring field regions.

The dielectric layer pattern 108a may be formed on the floating gate pattern 120. The dielectric layer pattern 108a may include a first silicon oxide layer (not shown), a silicon nitride layer (not shown) and a second silicon oxide layer (not shown) that may be sequentially stacked on the floating gate pattern 120.

The control gate pattern 112 may be formed on the dielectric layer pattern 108a. The control gate pattern 112 may include a polysilicon layer pattern 120a and a conductive layer pattern 120b that may be sequentially stacked on the dielectric layer pattern 108a. The polysilicon layer pattern 120a may have sufficient thickness to cover the floating gate pattern 120, so that a gap between adjacent floating gate patterns 120 may be filled with the polysilicon layer pattern 120a. The conductive layer pattern 112b may include metal, for example, tungsten, tungsten silicide, and/or related materials.

The floating gate pattern 120 of example embodiment may have an L shape, so that neighboring floating gate patterns may be spaced apart from each other by an increased interval compared to a floating gate pattern having a flat shape of the conventional art. In addition, the surface area of opposite surfaces of the neighboring floating gate patterns may be smaller, thereby sufficiently preventing or reducing cell disturbance between neighboring floating gate patterns.

Further, due to the height of the floating gate pattern 120, the coupling ratio of the device may be improved, which may enhance operation characteristics of the non-volatile memory device.

Although not shown, two adjacent floating gate patterns may be symmetrical with respect to each other when the cell disturbance between the adjacent floating gate patterns is sufficiently prevented or redcued.

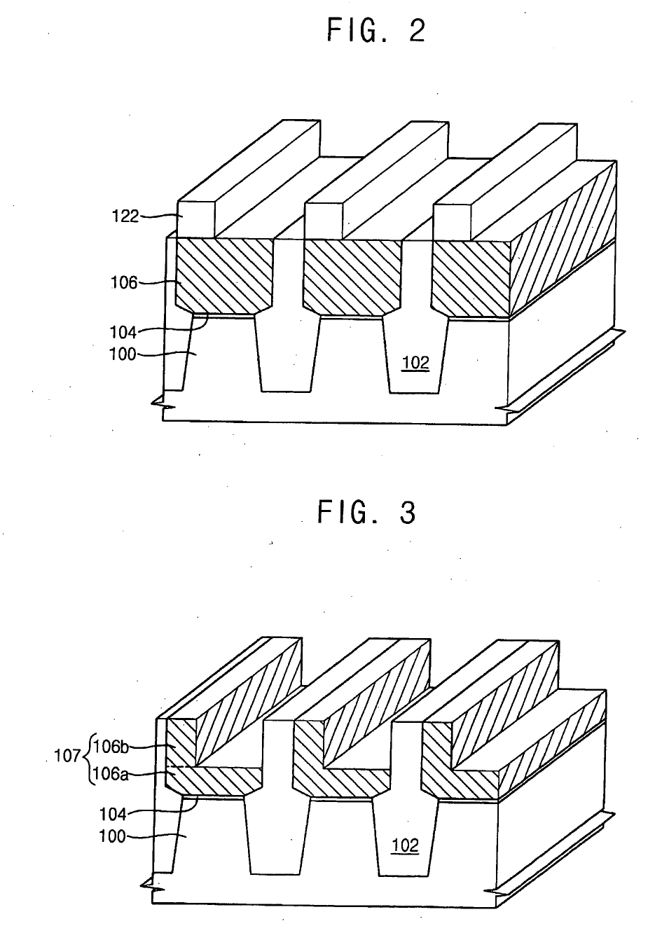

FIGS. 2 to 6 are example perspective views illustrating processing to manufacture the non-volatile semiconductor memory device shown in FIG. 1.

Referring to FIG. 2, a preliminary isolation layer 102 may be formed at an upper portion of the substrate 100. An active region on which various conductive structures may be formed may be defined on the substrate 100 by the preliminary isolation layer 102 in a field region of the substrate 100. The preliminary isolation layer 102 may be formed by a trench isolation process as follows.

A pad oxide layer (not shown) and a hard mask layer (not shown) may be sequentially formed on the substrate 100. The hard mask layer may be formed to a thickness substantially greater than a desired thickness of the floating gate pattern. The hard mask layer and the pad oxide layer may be partially etched by a photolithographic process to form a mask pattern (not shown) including a pad oxide layer pattern (not shown) and a hard mask pattern (not shown). The mask pattern may extend along the first direction.

The substrate 100 may be partially etched using the mask pattern as an etching mask to form a trench (not shown) at an upper portion of the substrate 100. An insulation layer (not shown) may be formed on the substrate 100 to a sufficient thickness to fill the trench. The insulation layer may be removed by a planarization process until a top surface of the mask pattern may be exposed to form the preliminary isolation layer 102 at the upper portion of the substrate 100.

The hard mask layer pattern and the pad oxide layer pattern may be removed from the substrate 100 by an etching process, and the active region of the substrate 100 may be exposed to form an opening (not shown), for example, a sidewall of the preliminary isolation layer 102 and a top surface of the active region of the substrate 100 may be exposed. In example embodiments, an upper sidewall of the preliminary isolation layer 102 may be further etched in the etching process for forming the opening, so that a size of an upper portion of the opening may be greater than that of a lower portion of the opening. The opening may be used for forming a floating gate in a subsequent process.

A tunnel oxide layer 104 may be formed on the exposed substrate 100 of the active region. The tunnel oxide layer 104 may be formed using a material having relatively good electrical characteristics such as silicon oxide, so that carriers such as electrons and holes easily migrate through the tunnel oxide layer 104. The tunnel oxide layer 104 may be formed by a thermal oxidation process. The tunnel oxide layer 104 may have a thickness of about 40 Å to about 100 Å.

A first conductive layer (not shown) may be formed on the substrate 100 including the tunnel oxide layer 104 to a sufficient thickness to fill the opening. The first conductive layer may be formed using doped polysilicon. The first conductive layer may be formed by a chemical vapor deposition (CVD) process. The first conductive layer may be patterned into a floating gate in subsequent processes.

The first conductive layer may be removed from the substrate 100 by a planarization process until a top surface of the preliminary isolation layer 102 may be exposed, to form a first preliminary floating gate pattern 106 on the tunnel oxide layer 104 extending along the first direction. As shown in FIG. 2, a top surface of the first preliminary floating gate pattern 106 may be flat and coplanar with a top surface of the preliminary isolation layer 102.

A photoresist film (not shown) may be formed on the preliminary isolation layer 102 and the first preliminary floating gate pattern 106, and the photoresist layer may be exposed and developed to form a photoresist pattern 122 on the first preliminary floating gate pattern 106 through which the first preliminary floating gate pattern 106 may be partially exposed. In an example embodiment, all portions of the first preliminary floating gate pattern 106 extending from a central portion thereof to a first edge portion thereof may be exposed through the photoresist pattern 122 shaped into a stripe in the first direction.

The photoresist pattern 122 may cover the preliminary isolation layer 102 when the photoresist pattern 122 does not cover a second edge portion of the first preliminary floating gate pattern 106. The second edge portion of the first preliminary floating gate pattern 106 may be symmetrical to the first edge portion thereof with respect to a central axis.

Referring to FIG. 3, the first preliminary floating gate pattern 106 may be partially etched from the substrate 100 to a desired depth using the photoresist pattern 122 as an etching mask, so that an upper portion of the first preliminary floating gate pattern 106 may be partially removed from the substrate and a lower portion of the first preliminary floating gate pattern 106 remains unetched in the opening to form a second preliminary floating gate pattern 107. That is, the second preliminary floating gate pattern 107 may include a lower pattern 106a having a first width that may be located on the tunnel oxide layer 104 and an upper pattern 106b having a second width that may be located on the lower pattern 106a. The second width may be smaller than the first width. As a result, the second preliminary floating gate pattern 107 may be formed into an L-shape.

The first preliminary floating gate pattern 106 may be partially etched from the substrate 100 by a dry etching process regardless of an etching selectivity with respect to the preliminary isolation layer 102. However, in an example embodiment, the first preliminary floating gate pattern 106 may be etched from the substrate 100 at a relatively high etching selectivity with respect to the preliminary isolation layer 102, so that the preliminary isolation layer 102 may be hardly etched from the substrate 100 in the etching process for forming the second preliminary floating gate pattern 107 to thereby improve reproducibility of the process.

An increased area of the floating gate pattern may increase a capacitance C_{ONO} between the floating gate pattern and control gate pattern. However, because an integration degree of a semiconductor device may be decreased according to the increased width of the floating gate pattern, it may be desirable to increase a height of the floating gate pattern rather than width. Although, there may be a problem that increasing the height of the floating gate pattern may undesirably generate the cell disturbance between neighboring cells more frequently.

However, the second preliminary floating gate pattern 107 may be formed to an L-shape so that the second preliminary floating gate pattern 107 may be spaced apart from a neighboring second preliminary floating gate pattern by an increased space, to thereby prevent or reduce cell disturbance. Thus, the second preliminary floating gate pattern 107 may be formed to a sufficient height, regardless of cell disturbance.

After an etching process, the photoresist pattern 122 may be removed by an ashing process and/or a stripping process.

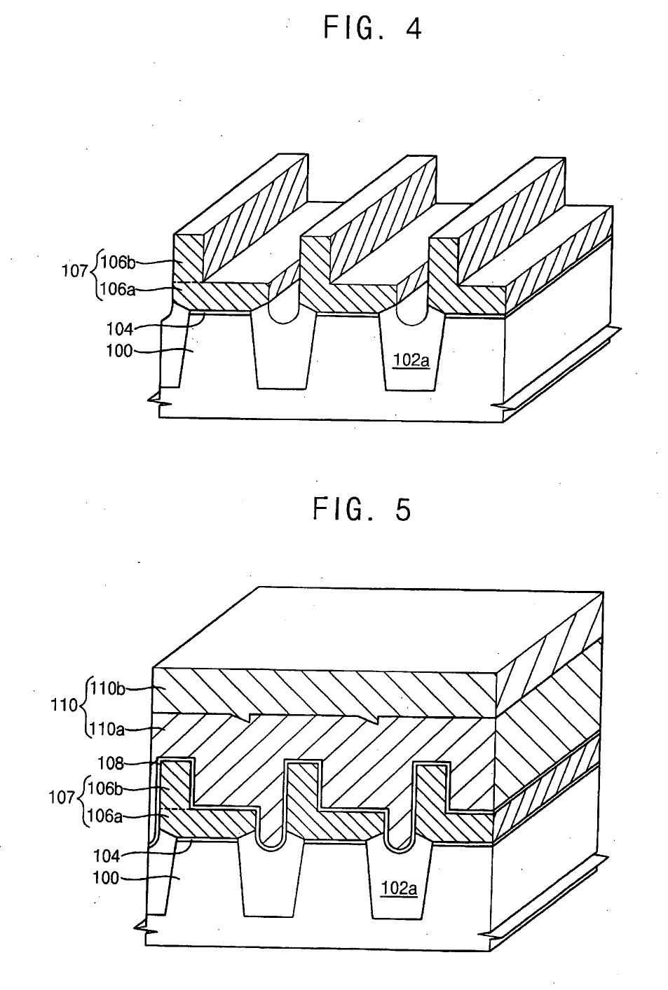

Referring to FIG. 4, the preliminary isolation layer 102 may be etched to form an isolation layer 102a having a recess at a central portion thereof. The exposed portion of the preliminary isolation layer 102 may be etched by a wet etching process or a dry etching process. In example embodiments, the preliminary isolation layer 102 may be etched by a wet etching process, so that damage to the second preliminary floating gate pattern 107 may be minimized or reduced while etching the preliminary isolation layer 102. The second preliminary floating gate pattern 107 may be hardly etched by the wet etching process because the second preliminary floating gate having relatively high etching selectivity compared to the preliminary isolation 102. As a result of the wet etching process, a central portion of the preliminary isolation layer 102 may be lower than a top surface of the substrate 100 of the active region, thereby forming the isolation layer 102a having the recess at the central portion thereof.

Accordingly, a sidewall of the lower pattern 106a of the second preliminary floating gate pattern 107 may be exposed by the etching process for forming the isolation layer 102a, so that an effective surface area of a dielectric layer may be increased when the dielectric layer may be formed on the second preliminary floating gate pattern 107 in a subsequent process.

Referring to FIG. 5, the dielectric layer 108 may be conformally formed on upper surfaces and sidewalls of the second preliminary floating gate pattern 107 and on surfaces of the isolation layer 102a. The dielectric layer 108 may be formed of a material having a relatively relatively high dielectric constant such as an oxide/nitride/oxide (ONO) layer in which an oxide film, a nitride film and an oxide film may be sequentially stacked on the second preliminary floating gate pattern 107 and the isolation layer 102a. In example embodiments, the dielectric layer 108 may be formed to a uniform or sunstantially uniform thickness of about 100A to about 200A by a low pressure chemical vapor deposition (LPCVD) process.

A second conductive layer 110 may be formed on the dielectric layer 108. The second conductive layer 110 may be formed to include a doped polysilicon film 110a and a metal film 110b. For example, the doped polysilicon film 110a may be formed on the substrate 100 including the second preliminary floating gate pattern 107 and the recessed isolation layer 102a to a sufficient thickness to fill a space between the neighboring second preliminary floating gate patterns 107. The metal film 110b may be formed on the doped polysilicon film 110a. The metal film 110b may be formed to use a metal such as tungsten, tungsten silicide, etc.

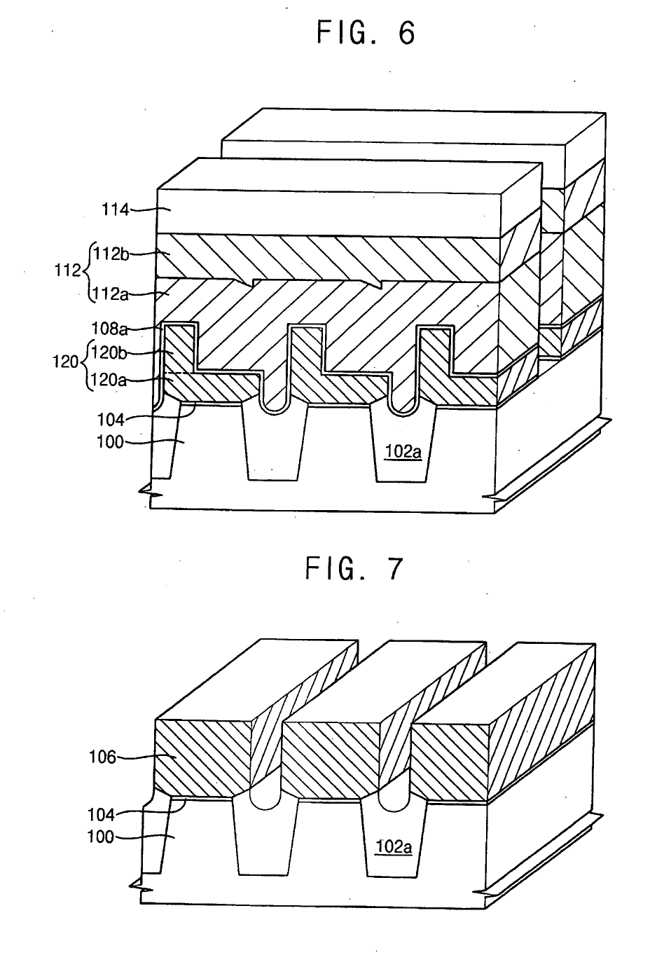

Referring to FIG. 6, an insulation layer pattern 114 may be formed on the second conductive layer 110. The insulation layer pattern 114 may be formed into a stripe shape extending in a second direction substantially perpendicular to the first direction.

The second conductive layer 110 may be partially etched away using the insulation layer pattern 114 as an etching mask to form a control gate pattern 112 extending in the second direction. The dielectric layer 108 and the second preliminary floating gate pattern 107 may be sequentially and partially etched to form a dielectric layer pattern 108a and a floating gate pattern 120 in the first direction. For example, the second preliminary floating gate pattern 107 extending in the first direction may be also patterned in the second direction perpendicular to the first direction, thus the floating gate pattern 120 may be isolated from one another on the active region of the substrate 100. Accordingly, the floating gate pattern 120 may be formed into an L-shape including a lower pattern 120a having a first width and an upper pattern 120b having a second width smaller than the first width.

FIGS. 7 to 9 are perspective views illustrating processing for another method of manufacturing the non-volatile semiconductor memory device shown in FIG. 1.

Referring to FIG. 7, a preliminary isolation layer (not shown) may be formed on a substrate 100 by the same process as described with reference to FIG. 2. An active region on which various conductive devices may be to be formed may be defined on the substrate 100 by the preliminary isolation layer. A tunnel oxide layer 104 and a first preliminary floating gate pattern 106 may be formed on the active region of the substrate 100. However, formation of the photoresist pattern on the first preliminary floating gate pattern 106 may be an optional process, which may be different from the processing described with reference to FIG. 2. In an example embodiment, the photoresist pattern may not be formed on the first preliminary floating gate pattern 106, but may be formed in subsequent processing.

The preliminary isolation layer may be partially etched away either by a dry etching process or a wet etching process to form an isolation layer 102a having a recess at a central portion thereof. In an example embodiment, the preliminary isolation layer may be partially etched by a wet etching process, so that damage to the first preliminary floating gate pattern 106 due to the etching process for forming the isolation layer 102a may be minimized or reduced. The first. preliminary floating gate pattern 106 may be hardly etched away by the wet etching process against the preliminary isolation layer.

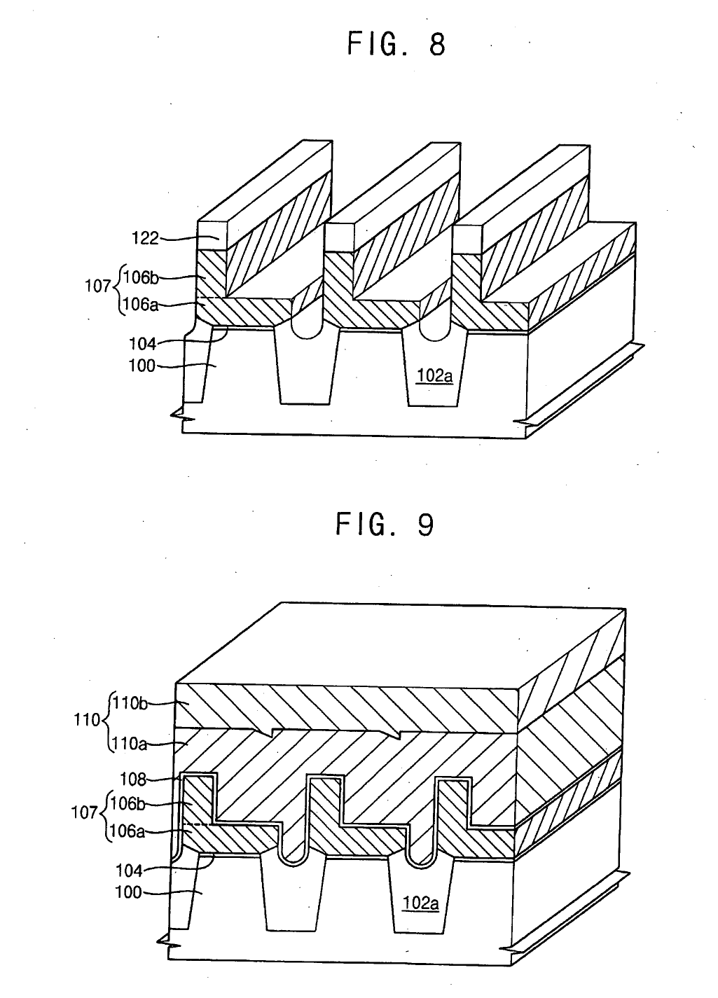

Referring to FIG. 8, a photoresist layer (not shown) may be formed on the isolation layer 102a and the first preliminary floating gate pattern 106, and formed into a photoresist pattern 122 by an exposure process and a development process. The first preliminary floating gate pattern 106 may be partially exposed through the photoresist pattern 122. The photoresist pattern 122 may be formed into a stripe shape extending in the first direction, and the first preliminary floating gate pattern 106 may be partially exposed.

The photoresist pattern 122 may partially or completely cover the preliminary isolation layer 102 where the photoresist pattern 122 does not cover the adjacent first preliminary floating gate pattern 106.

The first preliminary floating gate pattern 106 may be partially etched away to a predetermined or desired depth using the photoresist pattern 122 as an etching mask, so that an upper portion of the first preliminary floating gate pattern 106 may be partially removed and a lower portion of the first preliminary floating gate pattern 106 remains unetched on the tunnel oxide layer 104, to form a second preliminary floating gate pattern 107 on the tunnel oxide layer 104. That is, the second preliminary floating gate pattern 107 may include a lower pattern 106a having a first width that may be located on the tunnel oxide layer 104 and an upper pattern 106b having a second width that may be located on the lower pattern 106a, where the second width may be smaller than the first width. The first preliminary floating gate pattern 106 may be partially etched away by a dry etching process regardless of an etching selectivity with respect to the preliminary isolation layer 102. However, in an example embodiment, the first preliminary floating gate pattern 106 may be etched away at a relatively high etching selectivity with respect to the preliminary isolation layer 102, so that the preliminary isolation layer 102 may be hardly etched away in the etching process for forming the second preliminary floating gate pattern 107 to thereby improve reproducibility of the process.

After an etching process, the photoresist pattern 122 may be removed from the second preliminary floating gate pattern 107 by an ashing process and/or a stripping process.

Referring to FIG. 9, a dielectric layer 108 may be conformally formed on upper surfaces and sidewalls of the second preliminary floating gate pattern 107 and on surfaces of the isolation layer 102a.

A second conductive layer 110 may be formed on the dielectric layer 108. The second conductive layer 110 may be formed including a doped polysilicon film 110a and a metal film 110b. For example, the doped polysilicon film 110a may be formed on the substrate 100 including the second preliminary floating gate pattern 107 and the recessed isolation layer 102a to a sufficient thickness to fill a space between the neighboring second preliminary floating gate patterns 107. The metal film 110b may be formed on the doped polysilicon film 110a. The metal film 110b may be formed using a metal such as tungsten, tungsten silicide, etc.

An insulation layer pattern 114 may be further formed on the second conductive layer 110, as described with reference to FIG. 5. The insulation layer pattern 114 may be formed into a stripe shape extending in a second direction substantially perpendicular to the first direction.

The second conductive layer 110 may be partially etched using the insulation layer pattern 114 as an etching mask to form a control gate pattern 112 extending in the second direction and a floating gate pattern 120. The dielectric layer 108 and the second preliminary floating gate pattern 107 may be sequentially and partially etched to form a dielectric layer pattern 108a and a floating gate pattern 120 in the first direction. For example, the second preliminary floating gate pattern 107 extending in the first direction may be also patterned in the second direction perpendicular to the first direction, thus the floating gate pattern 120 may be isolated from one another on the active region of the substrate 100. Accordingly, the floating gate pattern 120 may be formed into an L-shape including a lower pattern 120a having a first width and an upper pattern 1 20b having a second width smaller than the first width.

Although not shown, after the control gate pattern 112 may be formed over the substrate 100, an insulating interlayer may be further formed on the insulation layer pattern 114 to cover the control gate pattern 112. In addition, a metal wiring electrically connected to a semiconductor device may be formed.

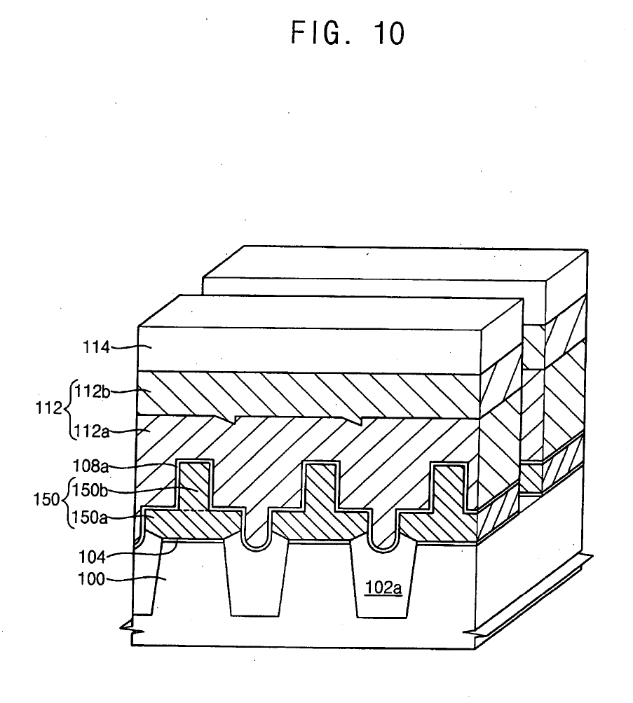

FIG. 10 is a perspective view illustrating a non-volatile semiconductor memory device in accordance with an example embodiment. A non-volatile semiconductor memory device in accordance with an example embodiment may be substantially identical to the non-volatile semiconductor memory device shown in FIG. 1 except a shape of the floating gate pattern (for example, the shape of the second preliminary floating gate).

Referring to FIG. 10, a non-volatile semiconductor memory device in accordance with an example embodiment may include a substrate 100, a tunnel oxide layer 104, a floating gate pattern 150, a dielectric layer pattern 108a and a control gate pattern 112.

The substrate 100 may include an isolation layer 102a that divides the substrate 100 into an isolation region and an active region. The tunnel oxide layer 104 may be formed on the active region of the substrate 100.

The floating gate pattern 150 may be located on the isolation layer 102a and the tunnel oxide layer 104. The floating gate pattern 150 may include a lower pattern 150a having a first width that may be located on the tunnel oxide layer pattern 104 and an upper pattern 150b having a second width that may protrude from a portion, for example, a central portion of the first pattern 150a, where the second width may be smaller than the first width. That is, the floating gate pattern 150 may have a cross-sectional shape of an “inverted T” or “⊥.” In example embodiments, the floating gate pattern 150 may include polysilicon doped with impurities. As an example embodiment, a bottom of the floating gate pattern 150 makes contact with the tunnel oxide layer 104 and outer portions of neighboring isolation layers 102a.

The dielectric layer pattern 108a may be formed on the floating gate pattern 150. The control gate pattern 112 may be formed on the dielectric layer pattern 108a.

The floating gate pattern 150 of example embodiments may have the cross-sectional shape of an “inverted T” or “⊥”, so that neighboring floating gate patterns may be spaced apart from each other by an increased space compared to a floating gate pattern having a conventional flat shape. Because the space between a neighboring floating gate patterns may be increased, cell disturbance between the neighboring floating gate patterns 150 may be sufficiently prevented or reduced.

Further, the floating gate pattern 150 may have a sufficient height, so that a coupling ratio between the floating gate and control gate may be increased to thereby improve the operation characteristics of the non-volatile memory device.

The non-volatile memory device may be manufactured by similar processing as described with reference to FIGS. 2 to 6, except the preliminary floating gate pattern may be formed to use a photoresist pattern that covers a central portion of the first conductive pattern and exposes both side portions thereof as it may be known to those with ordinary skills in the art.

According to example embodiments, an effective surface area between the control gate and the floating gate may be optimized or improved without an increase of a flat area of a cell, to thereby increase a capacitance of a floating gate pattern without increasing the size of the cell. Thus, a coupling ratio of the non-volatile memory device may be increased to enhance efficiency in programming and erasing data in the memory device. Further, cell disturbance between neighboring floating gate patterns may be suppressed or reduced, so that a threshold voltage of each cell may be stably distributed and a malfunction of a device may be prevented or reduced.

The foregoing is illustrative of example embodiments and is not to be construed as limiting thereof. Although example embodiments have been described, those skilled in the art will readily appreciate that many modifications are possible without materially departing from the novel teachings and advantages contained herein. Accordingly, all such modifications may be intended to be included within the scope of the claims. In the claims, means-plus-function clauses may be intended to cover the structures described herein as performing the recited function and not only structural equivalents but also equivalent structures. Therefore, it is to be understood that the foregoing is illustrative of example embodiments and is not to be construed as limited to the specific example embodiments disclosed, and that modifications to the disclosed example embodiments, as well as other embodiments, may be intended to be included within the scope of the appended claims. Example embodiments are defined by the following claims, with equivalents of the claims to be included therein.

What is claimed is:

1. A non-volatile semiconductor memory device, comprising:
a substrate including an active region defined by a field region in which an isolation layer is formed;
a tunnel oxide layer formed on the active region of the substrate;
a floating gate pattern including a lower part having a first width that is formed on the tunnel oxide layer and an upper part having a second width that is formed on the lower pattern, where the second width is substantially smaller than the first width;
a dielectric layer pattern formed on the floating gate pattern; and
a control gate pattern formed on the dielectric layer pattern.

2. The device of claim 1, wherein the upper part is located on a central portion of the lower part or on a side portion of the lower pattern.

3. The device of claim 1, wherein a cross-sectional shape of the floating gate pattern may have a substantially “L” shape or an inverted “T” or “⊥” shape.

4. The device of claim 1, wherein the control gate pattern comprises a polysilicon film and a metal film.

5. The device of claim 1, wherein the isolation layer comprises a recessed portion at a central portion thereof.

6. A method of manufacturing a non-volatile semiconductor memory device, comprising:
forming an isolation layer on a field region of a substrate, an active region being defined on the substrate by the isolation layer in a field region;
forming a tunnel oxide layer on the active region of the substrate;
forming a preliminary floating gate pattern including a lower part having a first width that is formed on the tunnel oxide layer and an upper part having a second width that is formed on the lower part, the second width being substantially smaller than the first width;
forming a dielectric layer on the preliminary floating gate pattern;
forming a control gate layer on the dielectric layer; and
patterning the control gate layer, the dielectric layer and the preliminary floating gate pattern to form a control gate pattern, a dielectric layer pattern and a floating gate pattern, respectively, on the active region of the substrate.

7. The method of claim 6, wherein forming the preliminary floating gate pattern comprises:
forming a first preliminary floating gate pattern on the tunnel oxide layer, p1 forming a mask pattern through which the first preliminary floating gate pattern is partially exposed; and
partially etching the first preliminary floating gate pattern to a depth to use the mask pattern as an etching mask, so that a lower portion of the first preliminary floating gate pattern has the first width and an upper portion of the first preliminary floating gate pattern has the second width.

8. The method of claim 7, wherein a side portion or a central portion of the first preliminary floating gate pattern is covered with the mask pattern.

9. The method of claim 7, wherein a top surface of the isolation layer is relatively higher than a surface of the active region of the substrate, and
wherein forming the first preliminary floating gate pattern comprises:
forming a conductive layer on the substrate to a thickness to fill a space between isolation layers adjacent to each other; and
planarizing the conductive layer until a top surface of the isolation layer is exposed.

10. The method of claim 7, after forming the first preliminary floating gate pattern, further comprising removing an upper portion of the isolation layer from the substrate.

11. The method of claim 6, after forming the preliminary floating gate pattern, further comprising removing an upper portion of the isolation layer.

12. The method of claim 6, wherein forming the control gate layer comprises:
forming a polysilicon film on the dielectric layer to fill a space between the preliminary floating gate patterns adjacent to each other; and
forming a conductive film including a metal on the polysilicon layer.
